(19) United States
(12) Patent Application Publication
(10) Pub. No.: US 2017/0294621 A1
(43) Pub. Date: Oct. 12, 2017

(54) DISPLAY DEVICE

(71) Applicant: Japan Display Inc., Tokyo (JP)

(72) Inventors: Toshiyuki HIGANO, Tokyo (JP); Yasushi KAWATA, Tokyo (JP)

(21) Appl. No.: 15/469,679

(22) Filed: Mar. 27, 2017

(30) Foreign Application Priority Data
Apr. 8, 2016 (JP) 2016-077911

(51) Int. Cl. H01L 51/52; H01L 27/32; H01L 51/00

(52) U.S. Cl. CPC H01L 51/5253; H01L 51/0097; H01L 27/3276; H01L 51/5281; G02F 1/133305

(57) ABSTRACT

A display device has both an array layer and a terminal part formed on a bendable substrate. An optical sheet is disposed to cover the array layer, and an overcoat is formed to cover the terminal part. The side surface of the optical sheet is inclined at an inclination angle with respect to the main surface of the substrate. The overcoat is in contact with the side surface of the optical sheet.

### CLAIM OF PRIORITY

The present application claims priority from Japanese Patent Application JP 2016-077911 filed on Apr. 8, 2016, the content of which is hereby incorporated by reference into this application.

### BACKGROUND OF THE INVENTION

### (1) Field of the Invention

The present invention relates to a display device, and more particularly, to a flexible display device which allows the substrate to be bent.

### (2) Description of the Related Art

The organic EL display device and the liquid crystal display device may be configured to reduce its thickness so as to be used while being flexibly bent. In this case, the thin glass or the thin resin may be used for forming the substrate that constitutes the device. The organic EL display device which employs no backlight is more suitable for thinning.

The display device includes various types of devices such as a TFT (Thin Film Transistor), a wiring, and a protective insulating film for protecting those devices. Upon bending of the display device, stress is applied to those devices, which may cause the risk of breaking the hard device, if any. In order to prevent the breakage, it is preferable to suppress bending stress applied to the respective devices upon bending of the display device.

The US laid-open application publication US2004/0354558 discloses the structure which prevents both tensile stress and compressive stress from being applied to the wiring upon bending of the display device for use by covering such wiring formed on the film-like substrate surface, and forming another film for alleviating the stress so as to suppress the bending stress applied to those devices.

### SUMMARY OF THE INVENTION

The protective layer is formed for protecting the TFT, the wiring and the like of the display device. The protective layer is often made of a resin, and capable of alleviating the compressive stress or the tensile stress applied to the wiring formed on the substrate. However, besides the mechanical protecting function, it is necessary to impart the function to the protective layer for keeping such device from outside air, especially moisture.

A plurality of types of protective layers are used in accordance with the respective locations of the display device. In order to protect the device such as the wiring from the outside air, each boundary of the protective layers has to be in close contact state so as to be kept air-tight. As the display device is used while having the display region bent, the stress is applied to the protective layer. This may cause crack in each boundary of the respective protective layers.

In the aforementioned case, moisture may penetrate through the crack into the display device, by which the light emitting device or liquid crystal, or the TFT, the wiring are corroded, resulting in reduced life of the display device. It is an object of the present invention to provide a flexible display device with high reliability by preventing crack between the protective layers when using the display device while being bent.

The representative implementation according to the present invention will be described in detail.
(1) A display device includes a display region and a terminal part formed on a bendable substrate. An optical sheet is disposed to cover the display region, and an overcoat is formed to cover the terminal part. A side surface of the optical sheet is inclined at an inclination angle with respect to a main surface of the substrate. The overcoat is in contact with the side surface of the optical sheet.
(2) A display device includes a display region and a terminal part formed on a bendable substrate. An optical sheet is disposed to cover the display region, and a flexible wiring substrate is connected to an end of the terminal part. An overcoat is formed to cover the terminal part. A side surface of the flexible wiring substrate connected to the terminal part has an inclination angle with respect to a main surface of the flexible wiring substrate. The overcoat is in contact with the side surface of the flexible wiring substrate.

### BRIEF DESCRIPTION OF THE DRAWINGS

FIG. 1 is a development view of a flexible display device;

FIG. 2 is a sectional view taken along line A-A of FIG. 1;

FIG. 3 is a sectional view representing the state that the display device shown in FIG. 1 is bent at a terminal part;

FIG. 4 is a sectional view representing the disadvantage resulting from non-use of the present invention;

FIG. 5 is a sectional view of the present invention;

FIG. 6 is a sectional view schematically showing an effect of the present invention;

FIG. 7 is a sectional view of a display region of an organic EL display device;

FIG. 8 is a sectional view of the organic EL display device, representing a boundary between the display region and the terminal part;

FIG. 9 is a sectional view representing an example of the method of forming a polarizing plate according to the present invention;

FIG. 10 is a view showing a laser irradiation profile;

FIG. 11 is a sectional view representing an example of a configuration of an end of the polarizing plate;

FIG. 12 is a sectional view representing another example of the present invention; and

FIG. 13 is a sectional view representing a case that the present invention is applied to a part of the terminal part connected to a flexible wiring substrate at the terminal part.

### DETAILED DESCRIPTION OF THE PREFERRED EMBODIMENTS

The present invention will be described referring to the following embodiment.

### First Embodiment

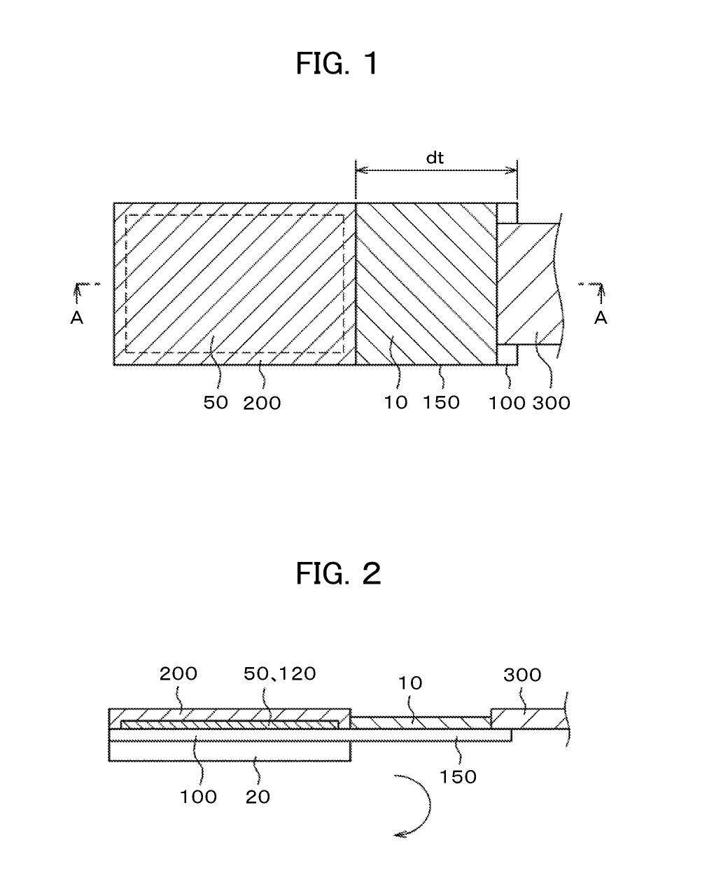

FIG. 1 is a plan view of an organic EL display device which includes a flexible substrate 100 to which the present invention is applied. The flexible display device according to the present invention is intended to be bent at a terminal part 150. FIG. 1 is a development view of the device in the state before the terminal part 150 is bent. Since the flexible display device as shown in FIG. 1 is bent at the terminal part 150, its length dt is set to be longer than the usual dimension.

Referring to a display region 50 in FIG. 1, an organic EL light emitting device, the TFT for controlling the light emitting device, and the wiring are formed on a flexible substrate 100. A polarizing plate 200 is disposed to cover the display region 50. The polarizing plate 200 of the organic EL display device is used for the antireflection purpose. The terminal part 150 is positioned to the right of the polarizing plate 200. A flexible wiring substrate 300 for supplying power and signals to the organic EL display device is connected to an end of the terminal part 150. The terminal part 150 is covered with an overcoat 10.

FIG. 2 is a sectional view taken along line A-A of FIG. 1. Referring to FIG. 2, the display region 50 is formed on the flexible substrate 100 made of polyimide. The flexible substrate 100 has a thickness ranging from 10 μm to 20 μm. The display region 50 on which an organic light emitting device array, a TFT array, and the wiring are formed will be referred to as an array layer 120. The polarizing plate 200 is disposed to cover the array layer 120. The polarizing plate 200 is bonded to the display region with the adhesive material. The flexible substrate 100 has its thickness ranging from 10 μm to 20 μm. As the above-structured flexible display device is mechanically weak, and unstably shaped, a supporting substrate 20 is bonded to the lower surface of the flexible substrate 100, corresponding to the display region 50. The glass substrate or the resin substrate may be used for forming the supporting substrate 20 where necessary. It is also possible to select the thickness depending on the purpose. For example, the supporting substrate has its thickness ranging from approximately 0.1 mm to 0.5 mm.

As FIG. 2 shows, the supporting substrate 20 has a planar shape. It is also possible to impart curvature to the supporting substrate 20 so as to provide the display device with a curved display region. In other words, because of flexibility, the flexible substrate 100 may be easily deformed along the shape of the supporting substrate 20.

Referring to FIG. 2, the flexible substrate 100 extends rightward to constitute the terminal part 150. An end of the terminal part 150 is connected to the flexible wiring substrate 300 for supplying power and signals to the organic EL display device. As FIG. 2 shows, the terminal part 150 is longer than the corresponding part of the normal display device so as to be bent as indicated by arrow to reduce the planar dimension of the display device.

Referring to FIG. 2, the overcoat 10 is applied to the terminal part 150. The overcoat 10 which is made of a resin mechanically protects the wiring formed on the terminal part 150 as well as from outside air. As FIG. 2 shows, the terminal part 150 is configured to be bent, which may cause the risk of tensile stress applied to the wirings formed on the surface of the flexible substrate 100 upon bending, resulting in the wiring disconnection and breakage of the hard insulating layer. The overcoat 10 also serves to alleviate the tensile stress applied to the wirings formed on the terminal part 150.

The overcoat 10 is formed through ink jetting, and solidified through firing. Accordingly, the overcoat 10 is brought into close contact with each side surface of the polarizing plate 200 and the flexible wiring substrate 300. As a result, the wiring formed on the flexible substrate 100 is isolated from outside air. The overcoat 10 has its thickness ranging from 30 μm to 40 μm, for example, and is made of the resin softer than the material for forming the flexible substrate 100. That is, the thickness of the overcoat is larger than that of the flexible substrate. However, as the overcoat 10 is softer than the polyimide that constitutes the flexible substrate 100, the stress applied to the wiring formed on the flexible substrate is made smaller upon bending of the terminal part for keeping balance.

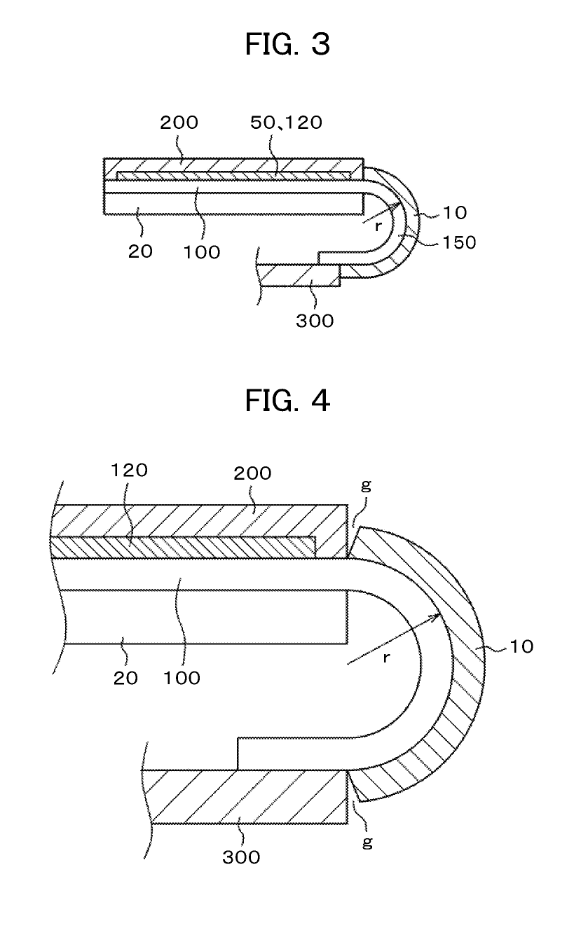

FIG. 3 is a sectional view representing the state that the organic EL display device is bent at the terminal part 150. Referring to FIG. 3, the terminal part of the flexible substrate 100 is configured to be bent first at the end of the supporting substrate, and turned to face the back side of the display region 50 while having a curvature radius r. As FIG. 3 shows, the curvature radius r on the surface of the terminal part 150 of the flexible substrate 100 is approximately 0.3 mm, for example.

As the curvature radius r indicated in FIG. 3 is very small, the substrate seems to be almost folded from the outer appearance view. Therefore, the stress generated in the flexible substrate 100 and the overcoat 10 will grow significantly. As FIG. 3 shows, the flexible substrate 100 as one body will not be easily broken by the stress. Meanwhile, the overcoat 10 has one end in contact with the polarizing plate 200, and the other end in contact with the flexible wiring substrate 300. Each adhesive strength at the contact parts, however, is not so strong.

The aforementioned state may cause the phenomenon, for example, separation of the overcoat 10 from the polarizing plate 200, or the flexible wiring substrate 300 at the respective interfaces. FIG. 4 is a sectional view showing the aforementioned phenomenon.

Referring to FIG. 4, the structure formed by laminating the flexible substrate 10 and the overcoat 10 is bent with the small curvature radius r to generate the tensile stress applied to the overcoat 10. As a result, a gap g is generated between the overcoat 10 and the polarizing plate 200, or between the overcoat 10 and the flexible wiring substrate 300. Because of the gap g, the wiring formed on the flexible substrate 100 is more susceptible to the influence of outside air, which may deteriorate reliability of the display device.

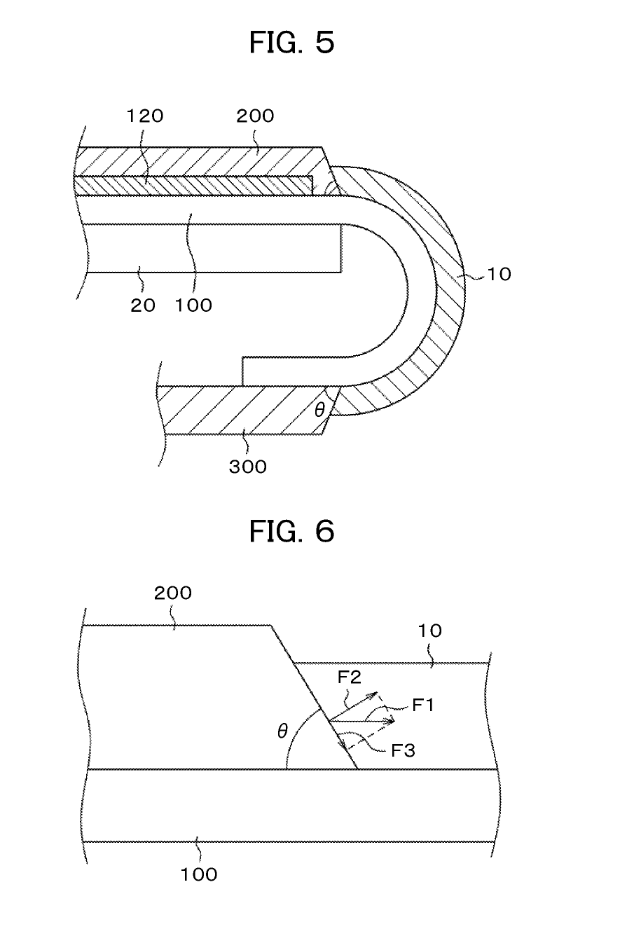

FIG. 5 is a sectional view of the structure according to the present invention, which is intended to cope with the aforementioned disadvantage. Referring to FIG. 5, the end side surface of the polarizing plate 200 or the flexible wiring substrate 300 is inclined at the inclination angle θ, and is brought into contact with the overcoat 10. This structure enhances the adhesive strength between the overcoat 10 and the polarizing plate 200, and between the overcoat 10 and the flexible wiring substrate 300, and prevents separation of the overcoat 10 at the respective interfaces.

The end side surface of the polarizing plate 200 or the flexible wiring substrate 300 is inclined to enhance the adhesive strength between the overcoat 10 and the polarizing plate 200, or between the overcoat 10 and the flexible wiring substrate 300. The above-described effect may be derived from the mechanism as shown in FIG. 6 in addition to the increased adhesive area resulting from the inclined interface.

FIG. 6 is a sectional view representing the interface between the polarizing plate 200 and the overcoat 10 according to the present invention. Referring to FIG. 6, the tensile stress F1 is applied to bend the flexible substrate 100 and the overcoat 10. As FIG. 6 indicates that, in the present invention, the end of the polarizing plate 200 is inclined at the inclination angle θ so that the tensile stress F1 is decomposed into F2 and F3. The force F2 will cause separation between the polarizing plate 200 and the overcoat 10, and the force F3 will act parallel to the interface between the polarizing plate and the overcoat.

As FIG. 6 shows, the force F2 which will cause separation between the polarizing plate 200 and the overcoat 10 is lessened by F1 cos θ. Meanwhile, increase in the contact area between the overcoat 10 and the polarizing plate 200 as a result of inclining the end of the polarizing plate 200 corresponds to 1/cos θ. Consequently, the peeling-off stress per unit area between the overcoat 10 and the polarizing plate 200 becomes (cos θ)², resulting in significantly large effect.

It is preferable to set the angle θ as shown in FIG. 6 to be in the range from 30° to 80°, and more preferably, from 45° to 70°. The larger the angle θ becomes, the less the effect of the present invention becomes. Meanwhile, the smaller the angle θ becomes, the larger the effect of the present invention becomes. However, this may make manufacturing of the polarizing plate 200 difficult. If the angle θ is too small, the side surface of the polarizing plate 200 may affect the display region.

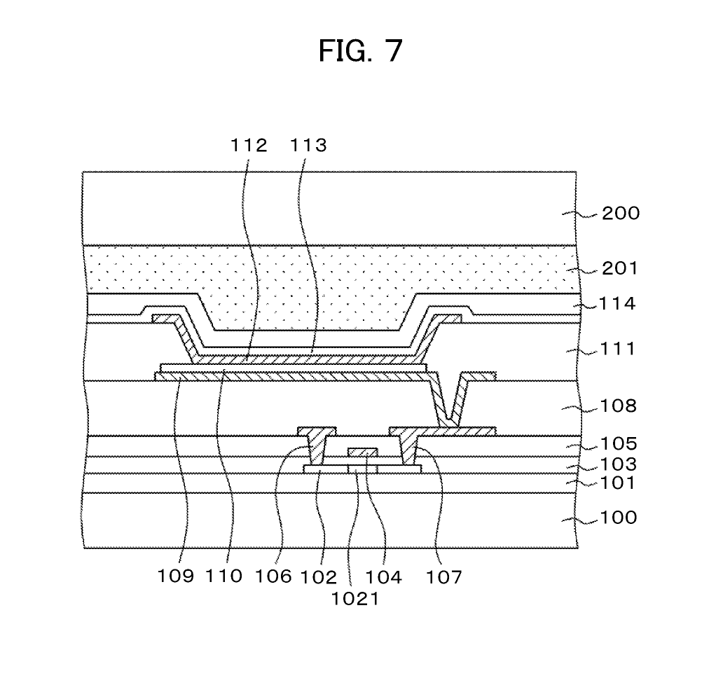

FIG. 7 is a sectional view of the display region of the organic EL display device of top emission type. Referring to FIG. 7, the polyimide is used for forming the flexible substrate 100 with its thickness ranging from 10 μm to 20 μm. Besides the polyimide, any other resin or glass may be used for forming the flexible substrate 100. A substrate-side barrier layer 101 is formed on the flexible substrate 100. The barrier layer 101 is intended to prevent penetration of moisture from the polyimide side. The substrate-side barrier layer 101 constitutes a body formed by laminating SiO and SiN. The substrate-side barrier layer 101 may be constituted by three layers of SiO with thickness of 50 nm, SiN with thickness of 50 nm, and SiO with thickness of 300 nm laminated from the substrate side. It is possible to allow SiO to include SiOx, and SiN to include SiNx.

A semiconductor layer 102 is formed on the substrate-side barrier layer 101. The semiconductor layer 102 is produced by the process of forming a-Si through CVD, which is then converted into Poly-Si using excimer laser.

A gate insulating film 103 is formed by using SiO produced with TEOS (tetraethoxysilane) through the CVD while covering the semiconductor layer 102. A gate electrode 104 is formed on the gate insulating film 103. Then ion implantation is executed so that the part of the semiconductor layer 102 except the one corresponding to the gate electrode 104 becomes a conductive layer. The part of the semiconductor layer 102, which corresponds to the gate electrode 104 becomes a channel part 1021.

An interlayer insulating film 105 for covering the gate electrode 104 is made of SiN through the CVD. Then through holes are formed in the interlayer insulating film 105 and the gate insulating film 103 so that a drain electrode 106 and a source electrode 107 are connected. Referring to FIG. 7, an organic passivation film 108 is formed to cover the drain electrode 106, the source electrode 107, and the interlayer insulating film 105. The organic passivation film 108 serving as a flattening film is configured to have the large thickness ranging from 2 μm to 3 μm. The organic passivation film 108 is made of, for example, an acrylic resin.

A reflection electrode 109 is formed on the organic passivation film 108, on which a lower electrode 110 is formed as the anode constituted by the transparent conductive film such as ITO. The reflection electrode 109 is made of an Al alloy with high reflectivity. The reflection electrode 109 is connected to the source electrode 107 of the TFT via the through hole formed in the organic passivation film 108.

An acrylic bank 111 is formed while surrounding the lower electrode 110. The bank 111 is provided in order to prevent conduction failure caused by the step-cut of an organic EL layer 112 including the light emitting layer and an upper electrode 113 which are formed in the subsequent step. The bank 111 is formed by applying the transparent resin such as the acrylic resin over the entire surface, and forming the hole in the part corresponding to the lower electrode 110 for taking light.

Referring to FIG. 7, the organic EL layer 112 formed on the lower electrode 110 is constituted by an electron injection layer, an electron transport layer, a light emitting layer, a hole transport layer, a hole injection layer and the like. The upper electrode 113 is formed on the organic EL layer 112 as a cathode. The upper electrode is constituted by an IZO (Indium Zinc Oxide), an ITO (Indium Tin Oxide) and the like as the transparent conductive film. It may also be constituted by a thin metal film such as silver.

Then, a surface barrier layer 114 made of SiN through the CVD is formed on the upper electrode 113 for the purpose of preventing penetration of moisture from the side of the upper electrode 113. As the organic EL layer 112 is weak to heat, the surface barrier layer 114 is formed through the CVD at low temperature of approximately 100° C.

The reflection electrode 110 may cause the screen of the organic EL display device of top emission type to deteriorate its contrast as a result of reflecting the outdoor light. In order to solve the aforementioned problem, the polarizing plate 200 is disposed on the surface to prevent reflection of the outdoor light. One surface of the polarizing plate 200 includes the adhesive material 201 which is pressure bonded to the surface barrier layer 114 for adhesion to the organic EL display device. The adhesive material 201 has its thickness of approximately 30 μm, and the polarizing plate 200 has its thickness of approximately 100 μm. As FIGS. 2 to 5 show, the polarizing plate 200 and the adhesive material 201 are formed to cover periphery of the array layer.

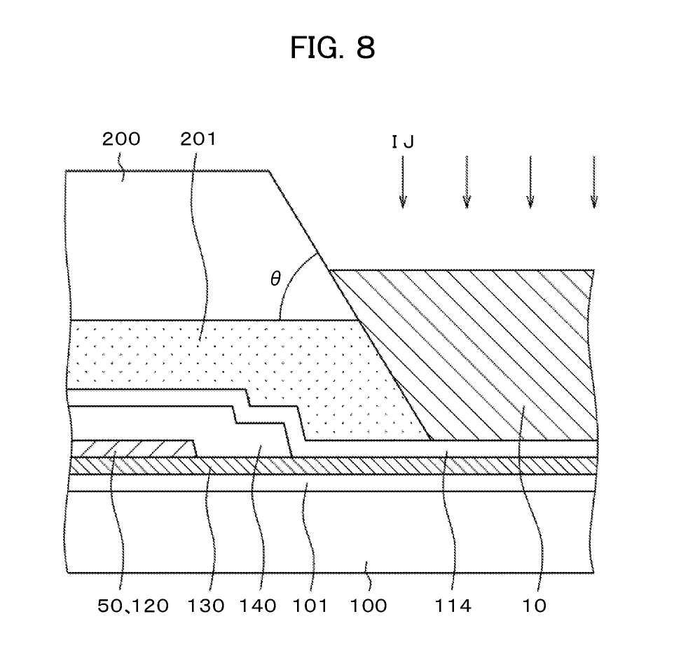

FIG. 8 is a sectional view of the organic EL display device, specifically, the region around the boundary between the display region, that is, the array layer 120 and the terminal part. Referring to FIG. 8, the substrate-side barrier layer 101 is formed on the flexible substrate 100 made of polyimide, on which a wiring layer 130 is formed. The wiring layer 130 refers to the general term of the wiring layer formed on the same layer as the gate electrode 104, or the drain electrode 106, the source electrode 107 and the like. The wiring layer 130 extends from the display region to the terminal part.

Referring to FIG. 8, the array layer 120 is formed on the wiring layer 130. The array layer 120 refers to the general term of the organic EL layer 112 and the like as shown in FIG. 7. An organic film 140 which covers the array layer 120 is the same as the one constituting the bank 111. The surface barrier layer 114 formed to cover the organic film 140 extends from the display region 50 to the terminal part, and covers the wiring layer 130 at the terminal part.

The polarizing plate 200 is disposed to cover the array layer 120, the organic film 140 and the like via the adhesive material 201. As FIG. 8 shows, each end side surface of the polarizing plate 200 and the adhesive material 201 is inclined at the inclination angle θ. Referring to FIG. 8, the overcoat 10 is formed at the right terminal part side, while covering the surface barrier layer 114. The overcoat 10 is applied through ink jetting and the like, and then solidified through firing. Referring to FIG. 8, the term IJ denotes ink jetting.

As FIG. 8 shows, according to the present invention, each end of the polarizing plate 200 and the adhesive material 201 is inclined at the inclination angle θ so as to keep the adhesive strength between the overcoat 10 and the polarizing plate 200 or the adhesive material 201 in stable state. In other words, the adhesive strength may be stably kept by increasing the adhesive area to the overcoat 10, and reducing the peeling-off stress on the interface between the overcoat 10 and the polarizing plate 200.

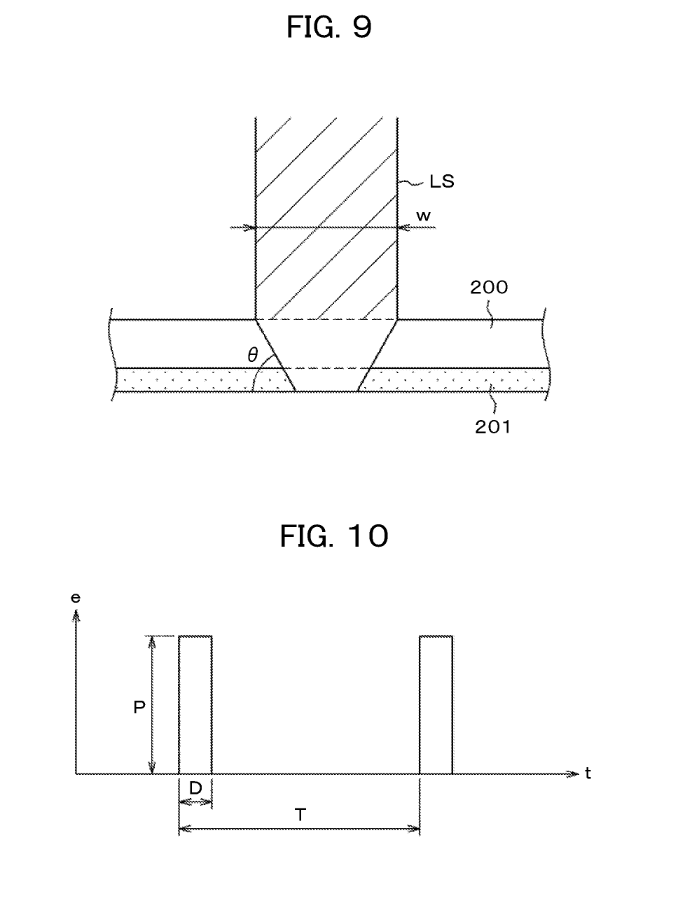

FIG. 9 is a sectional view representing an example of the process for forming the polarizing plate 200 as shown in FIG. 8. The polarizing plates 200 will be obtained by separation from the large mother polarizing plate so as to be employed for the respective organic EL display devices. Among various types of process for separating the respective polarizing plates from the mother polarizing plate, the separation process by means of laser is shown by FIG. 9. Referring to FIG. 9, the boundary of the polarizing plate is irradiated with laser beam LS so as to be vaporized. The laser beam LS as shown in FIG. 9 has a thickness w. Generally, the laser beam LS is not irradiated continuously, but intermittently at a predetermined cycle as shown in FIG. 10.

FIG. 10 shows an irradiation profile of the laser beam LS, having a Y-axis e indicating the laser beam energy, and an X-axis t indicating time. Referring to FIG. 10, the peak of the laser beam is designated as P, and the irradiation cycle is designated as T. By controlling the peak value P and the irradiation cycle T of the laser beam as shown in FIG. 10, and the width w of the laser beam as shown in FIG. 9, the inclination angle θ of the polarizing plate 200 at the end side surface as shown in FIG. 9 may be controlled.

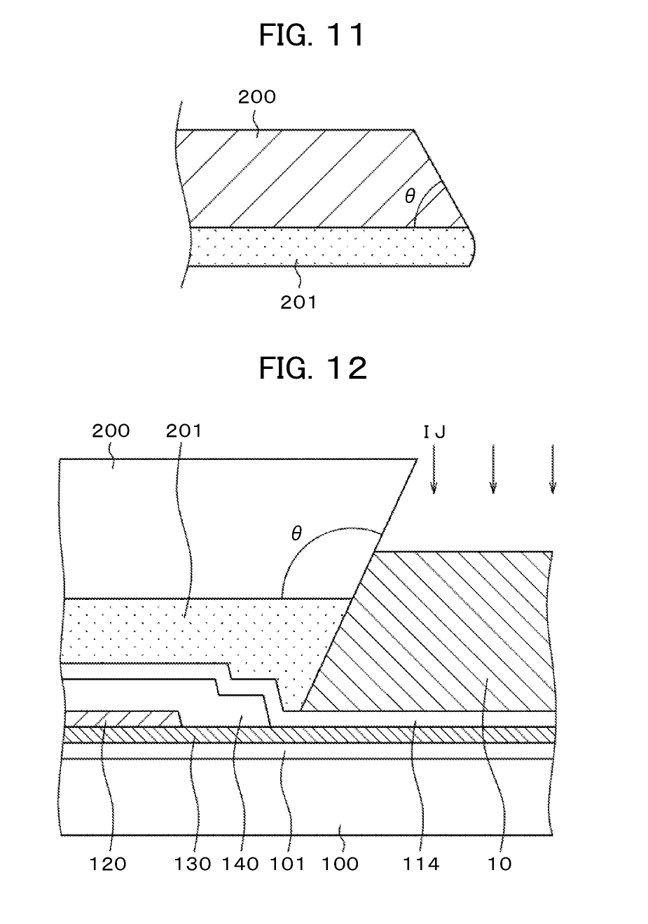

There may often be the case of difficulties in accurate formation of the angle as shown in FIG. 8 or 9 because the adhesive material 201 formed on the polarizing plate 200 exhibits too much plasticity. FIG. 11 is a sectional view of the polarizing plate 200 in the state as described above. FIG. 11 represents that the angle cannot be formed because of sagging of the adhesive material 201 at the end. The angle θ in the aforementioned state may be defined by the inclination of the end side surface of the polarizing plate 200 as shown in FIG. 11.

Explanations have been made with respect to a trapezoidal end side surface of the polarizing plate as shown in FIGS. 5 to 11. Meanwhile, an inverted trapezoidal end side surface of the polarizing plate 200, that is, in the overhung shape, may provide the effect similar to the one derived from the case as described referring to FIGS. 5 to 11. FIG. 12 is a sectional view of the area around the boundary between the array layer 120 and the terminal part as described above. The structure as shown in FIG. 12 is similar to the one as shown in FIG. 8 except the polarizing plate 200 in the overhung shape.

Referring to FIG. 12, the overcoat 10 is formed at the terminal part through ink jetting IJ. Because of low viscosity, the ink used for ink jetting IJ is allowed to easily reach the root end of the overhung polarizing plate 200. Then subsequent firing process provides the overcoat 10 as shown in FIG. 12. The thus structured polarizing plate 200 as shown in FIG. 12 may also enhance the adhesive strength between the overcoat and the polarizing plate by the increased adhesive area and dispersed tensile stress as described referring to FIG. 6.

In the case that the respective polarizing plates are separated from the mother polarizing plate, especially, each plate is separated while having its end side surface inclined with the mechanical blade, one of the polarizing plates is inclined in the forward direction, and the other polarizing plate is inclined in the inverted direction. The thus formed polarizing plate may have the end side surface as shown in FIG. 12.

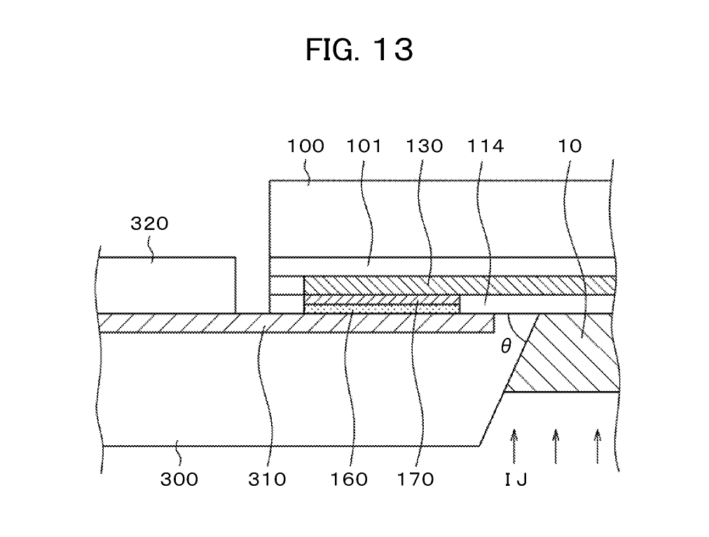

The adhesive strength between the end side surface of the polarizing plate 200 and the overcoat 10 has been mainly described. This may apply to the adhesive strength between the end side surface of the flexible wiring substrate 300 and the overcoat 10. FIG. 13 is a sectional view representing the adhesive state between the end side surface of the flexible wiring substrate 300 and the overcoat 10. Referring to FIG. 13, the substrate-side barrier layer 101 is applied onto the flexible substrate 100, and the wiring layer 130 thereon extends to reach around the end of the flexible substrate 100.

The surface barrier layer 114 which extends while covering the wiring layer 130 has its part connected to a wiring 310 at the side of the flexible wiring substrate 300 and the wiring layer 130 removed so that the wiring layer 130 is exposed. The exposed part of the wiring layer 130 is covered with an oxide conductive film 170 such as the ITO. An anisotropic conductive film (ACF) 160 is further applied to the oxide conductive film. The wiring 310 formed on the flexible wiring substrate 300 is subjected to thermocompression bonding for conduction. A flexible wiring substrate overcoat 320 is formed on the area at the side of the flexible wiring substrate 300 other than the connection part for protecting the wiring 310 at the side of the flexible wiring substrate.

Referring to FIG. 13, the end side surface of the flexible wiring substrate 300 is inclined at the angle θ, to which the overcoat 10 is bonded. As the end side surface of the flexible wiring substrate 300 is inclined, the adhesive strength between the flexible wiring substrate 300 and the overcoat 10 is improved as a result of the effect as shown in FIG. 6. This makes it possible to ensure connection reliability.

The polarizing plate for covering the display region has been described as above. It is possible to bond the optical sheet with low transmittance instead of the polarizing plate for the reflection preventive purpose. Specifically, the outdoor reflecting light passes the optical sheet twice, and the light from the light emitting device passes the optical sheet only once. The light transmittance of the optical sheet may be lowered to prevent deterioration in the contrast owing to the outdoor light. The present invention may be applied to the structure as described above.

The flexible substrate made of resin such as polyimide has been described as an example. The present invention may be applied to the use of glass for forming the substrate. Specifically, the thinned glass may be used for forming the flexible substrate.

The organic EL display device has been described as an example. The present invention may be applied to the liquid crystal display device. Specifically, use of the thinned glass substrate, or the resin for forming the substrate may produce the flexible display device as the liquid crystal display device because the problem of adhesion of the overcoat to the polarizing plate or the flexible wiring substrate via the interface is analogous to the case of the organic EL display device.

What is claimed is:

1. A display device having a display region and a terminal part formed on a bendable substrate, wherein:
an optical sheet is disposed to cover the display region, and an overcoat is formed to cover the terminal part;
a side surface of the optical sheet is inclined at an inclination angle with respect to a main surface of the substrate; and
the overcoat is in contact with the side surface of the optical sheet.

2. The display device according to claim 1, wherein the inclination angle of the side surface of the optical sheet with respect to the main surface of the substrate is in the range from 30° to 80°.

3. The display device according to claim 1, wherein the inclination angle of the side surface of the optical sheet with respect to the main surface of the substrate is in the range from 45° to 70°.

4. The display device according to claim 1, wherein the substrate is made of a resin.

5. The display device according to claim 1, wherein the substrate is made of a polyimide resin.

6. The display device according to claim 1, wherein the substrate is made of glass.

7. The display device according to claim 1, wherein the optical sheet is a polarizing plate.

8. The display device according to claim 1, wherein the overcoat is made of a resin.

9. The display device according to claim 1, wherein the display device is an organic EL display device.

10. The display device according to claim 1, wherein the display device is a liquid crystal display device.

11. A display device having a display region and a terminal part formed on a bendable substrate, wherein:
an optical sheet is disposed to cover the display region, and a flexible wiring substrate is connected to an end of the terminal part;
an overcoat is formed to cover the terminal part;
a side surface of the flexible wiring substrate connected to the terminal part has an inclination angle with respect to a main surface of the flexible wiring substrate; and
the overcoat is in contact with the side surface of the flexible wiring substrate.

12. The display device according to claim 11, wherein the inclination angle of the side surface of the flexible wiring substrate with respect to the main surface thereof is in the range from 30° to 80°.

13. The display device according to claim 11, wherein the inclination angle of the side surface of the flexible wiring substrate with respect to the main surface thereof is in the range from 45° to 70°

14. The display device according to claim 11, wherein the substrate is made of a polyimide resin.

15. The display device according to claim 11, wherein the substrate is made of glass.

16. The display device according to claim 11, wherein:
the side surface of the optical sheet is inclined at the inclination angle with respect to the main surface of the substrate; and
the overcoat is in contact with the side surface of the optical sheet.

17. The display device according to claim 11, wherein the display device is an organic EL display device.

18. The display device according to claim 11, wherein the display device is a liquid crystal display device.

19. The display device according to claim 1, wherein the substrate is folded back to a back side of the display region at the terminal part.

20. The display device according to claim 11, wherein the substrate is folded back to a back side of the display region at the terminal part.
